(19) United States
(12) Patent Application Publication
(10) Pub. No.: US 2021/0109146 A1
(43) Pub. Date: Apr. 15, 2021

(54) TRANSFORMER ANOMALY DETECTION WITH FREQUENCY RESPONSE ANALYSIS

(71) Applicant: ABB Schweiz AG, Baden (CH)

(72) Inventor: Luiz Cheim, St. Charles, MO (US)

(21) Appl. No.: 16/597,215

(22) Filed: Oct. 9, 2019

(51) Int. Cl. G01R 31/02; G06T 11/20

(52) U.S. Cl. CPC G01R 31/027; G06T 11/206

(57) ABSTRACT

A method is provided for detecting an anomalous frequency response analysis (FRA) test of a transformer. The method uses frequency response analysis to measure voltage amplitudes and frequencies in one winding of the transformer which result from an AC voltage applied to another winding of the transformer. Two statistical distributions are generated from the measured data and the statistical distributions are combined such that one distribution defines one axis, the other distribution defines another axis, and the probabilities of the distributions defines another axis.

### BACKGROUND

The present inventions relate generally to electrical transformers and the detection of an anomaly in the windings of a transformer.

Frequency response analysis can be used to test transformers. Typically, frequency response analysis (FRA) of a transformer involves applying an AC voltage of varying frequency to one winding of the transformer and monitoring the resulting AC voltage frequencies in another winding of the transformer. The results of this initial test may be saved and then compared to another similar test at a later time to identify frequency response changes. Changes in the frequency response of a transformer may be caused by an anomaly that occurs between the initial test and the later test. For example, a transformer that has been in operation for a number of years may experience a fault or short between the two tests which could result in excessive heat buildup in the transformer. Excessive mechanical forces on the windings may also be due to the action of elevated circulating currents and the respective interaction of the resulting magnetic fields. As a result, the windings of the transformer may be mechanically deformed, which would be useful to identify through an electrical test without having to physically inspect the windings.

However, one problem that has been experienced with frequency response analysis of transformers is the difficulty of comparing the results to identify an anomaly. Typically, highly trained professionals have been needed to interpret the results of a frequency response analysis because of the difficulty of identifying anomalies using the results. These difficulties arise for a number of reasons, such as the large range of frequencies utilized in the test, different types of transformer winding configurations that may produce different results, types of test equipment, test grounding methodologies, etc. This causes the cost of such tests to be expensive and time-consuming. Thus, it would be desirable to have a method for more easily interpreting frequency response analysis tests of transformers.

### SUMMARY

A method is described for detecting anomalous results when testing the windings of a transformer without needing to visibly inspect the windings. In the FRA test, an AC voltage is applied to a winding while varying the frequency of the voltage. The resulting AC voltage produced in another winding of the transformer is then measured. Statistical distributions are generated using the measured amplitude or frequency of the output response signals. Two statistical distributions are combined such that one statistical distribution defines one axis, another statistical distribution defines another axis, and the combined probabilities define a 3D probabilistic surface, in another axis perpendicular to the other two axes.

### BRIEF DESCRIPTION OF SEVERAL VIEWS OF THE DRAWINGS

The invention may be more fully understood by reading the following description in conjunction with the drawings, in which:

FIG. 1 is a schematic of a transformer;

FIG. 2 is an example of a frequency response chart;

FIG. 3 is a segment of the frequency response chart of FIG. 2;

FIG. 4A is a three-dimensional chart of probabilities based on FIG. 3;

FIG. 4B is another view of the three-dimensional chart of FIG. 4A;

FIG. 5 is another segment of the frequency response chart of FIG. 2;

FIG. 6A is a three-dimensional chart of probabilities based on FIG. 5;

FIG. 6B is another view of the three-dimensional chart of FIG. 6A;

FIG. 7 is another segment of the frequency response chart of FIG. 2;

FIG. 8A is a three-dimensional chart of probabilities based on FIG. 7;

FIG. 8B is another view of the three-dimensional chart of FIG. 8A;

FIG. 9 is another segment of the frequency response chart of FIG. 2;

FIG. 10A is a three-dimensional chart of probabilities based on FIG. 9;

FIG. 10B is another view of the three-dimensional chart of FIG. 10A;

FIG. 11 is another frequency response chart;

FIG. 12 is a segment of the frequency response chart of FIG. 11;

FIG. 13A is a three-dimensional chart of probabilities based on FIG. 12;

FIG. 13B is another view of the three-dimensional chart of FIG. 13A;

FIG. 14 is another frequency response chart of before and after tests of a transformer;

FIG. 15 is another frequency response chart with only the before test of FIG. 14;

FIG. 16 is a three-dimensional chart of probabilities based on FIG. 15;

FIG. 17 is another three-dimensional chart of probabilities based on FIG. 15;

FIG. 18A is another three-dimensional chart of probabilities based on FIG. 15;

FIG. 18B is another view of the three-dimensional chart of FIG. 18A;

FIG. 19A is another three-dimensional chart of probabilities based on FIG. 15;

FIG. 19B is another view of the three-dimensional chart of FIG. 19A;

FIG. 20 is a three-dimensional chart of probabilities based on FIG. 14;

FIG. 21 is another three-dimensional chart of probabilities based on FIG. 14;

FIG. 22 is view of a deformed transformer winding;

FIG. 23 is another frequency response chart of before and after tests of a transformer;

FIG. 24 is a three-dimensional chart of probabilities based on FIG. 23;

FIG. 25 is another three-dimensional chart of probabilities based on FIG. 23;

FIG. 26A is another three-dimensional chart of probabilities based on FIG. 23;

FIG. 26B is another view of the three-dimensional chart of FIG. 26A; and

FIG. 27 is another three-dimensional chart of probabilities based on FIG. 23.

### DETAILED DESCRIPTION

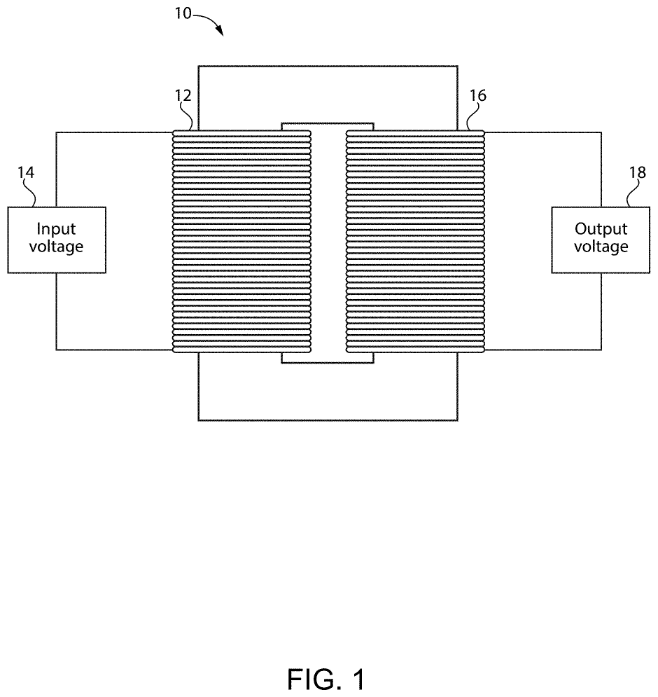

A conventional transformer 10 is shown in FIG. 1. A frequency response analysis of the transformer 10 may be conducted by applying an AC voltage to one of the windings 12 of the transformer 10 and varying the frequency of the AC voltage. This may be done with the input voltage 14 shown in FIG. 1. The AC voltage that is produced in the second winding 16 by the AC voltage of the first winding 14 is then measured, for example with the output voltage 18 shown in FIG. 1. The frequency range of the applied voltage typically varies from a few hertz to a few megahertz.

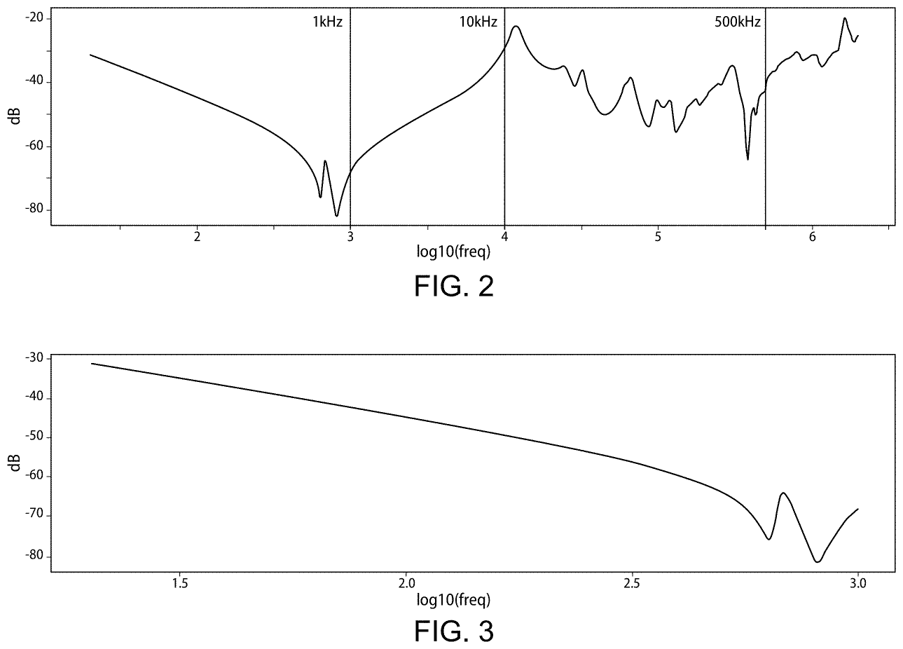

An output of a frequency response analysis is shown in FIG. 2. The varying frequency of the AC voltage is shown along the x-axis in logarithmic base 10 form. A comparison of the amplitudes of the input voltage and the output voltage at the varying frequencies is shown along the y-axis. Although various comparisons of the amplitudes may be used, a ratio of the input and output voltage amplitudes may be preferred. For example, a decibel (dB) reading may be used where the output voltage measured on the second winding is divided by the input voltage on the first winding. The log of the voltage ratio is then multiplied by 20 to calculate the dB reading. Although the dB reading is effectively unitless, the dB reading is defined by a voltage amplitude in that it is defined by the output voltage amplitude that is produced by the input voltage.

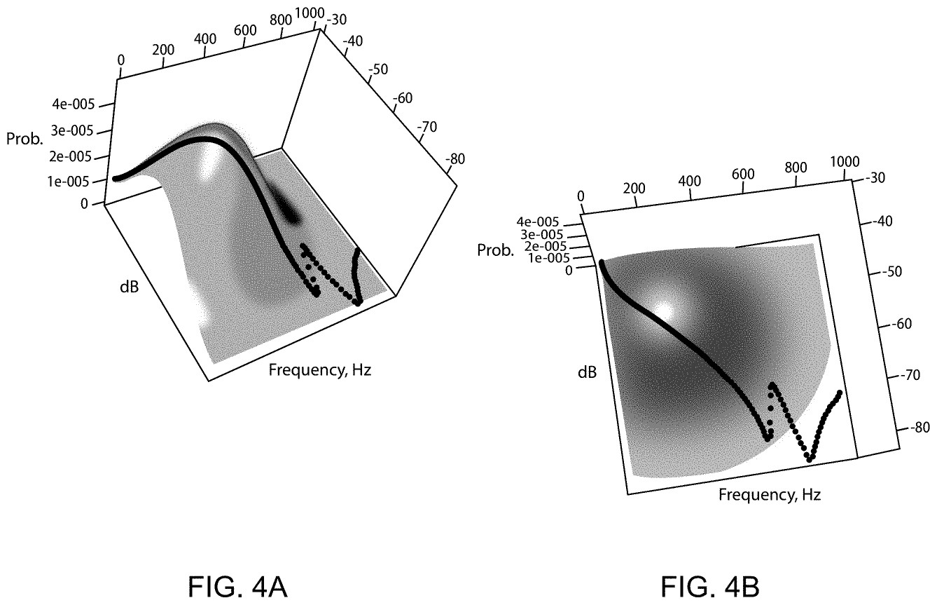

It may be desirable to evaluate the frequency response analysis chart in smaller sections of the frequency readings. Thus, the chart of FIG. 2 has been restricted in FIG. 3 to frequencies of 10 Hz to 1 kHz. A three-dimensional chart is shown in FIGS. 4A and 4B of the frequency response analysis chart of FIG. 3. FIGS. 4A and 4B show the same chart at different perspectives to more fully illustrate the three-dimensional aspect of the chart. One axis of the chart is defined by the frequencies of the frequency response chart of FIG. 3. Another axis of the chart is defined by the dB readings of the frequency response analysis chart of FIG. 3, which is understood to be defined by a voltage amplitude.

Unlike FIG. 3 (which is two-dimensional with the axes described thus far), FIGS. 4A and 4B include a third axis defined by probabilities. Preferably, a probabilistic surface is also included in the chart. The probabilistic surface may be determined in a two-step process. For example, in one step a first statistical distribution is generated using the frequency data irrespective of the dB data. In another step, a second statistical distribution is generated using the dB data irrespective of the frequency data. Thus, the two statistical distributions represent different frequency or amplitude data for a common range of frequencies. The first and second statistical distributions are then combined and plotted on the chart with the first statistical distribution defining the probabilistic surface along the frequency axis and the second statistical distribution defining the probabilistic surface along the dB axis.

Although it is possible that a variety of types of statistical distributions may be used and that different statistical distribution types may be used for separate axes, the embodiments herein use a Gaussian distribution defined by a mean and a standard deviation for both the frequency axis and the dB axis of the probabilistic surface. Thus, the resulting shape of the probabilistic surface is a bell curve along the frequency axis and a bell curve along the dB axis. This results in a three-dimensional bell shape although the bell-shape will not be circumferentially symmetric since the three-dimensional bell-shape is defined by two different bell curves.

A trace of the frequency and dB data of FIG. 3 may then be plotted on the three-dimensional chart of FIGS. 4A-4B. As shown, the trace generally follows the probabilistic surface since the probabilistic surface was derived from such data. As shown, the pattern of the trace follows a uniform, continuous path along the probabilistic surface.

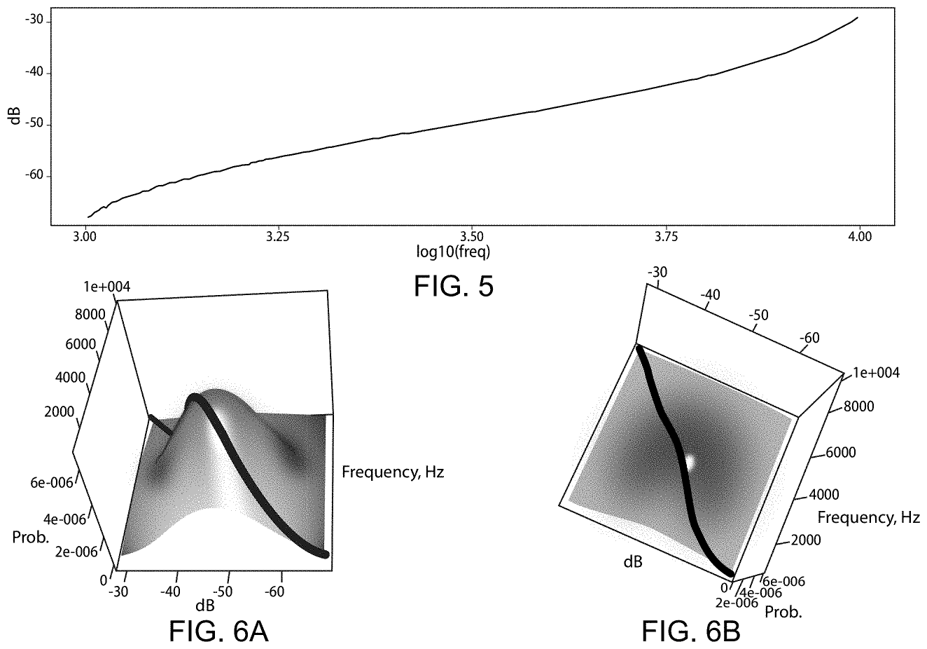

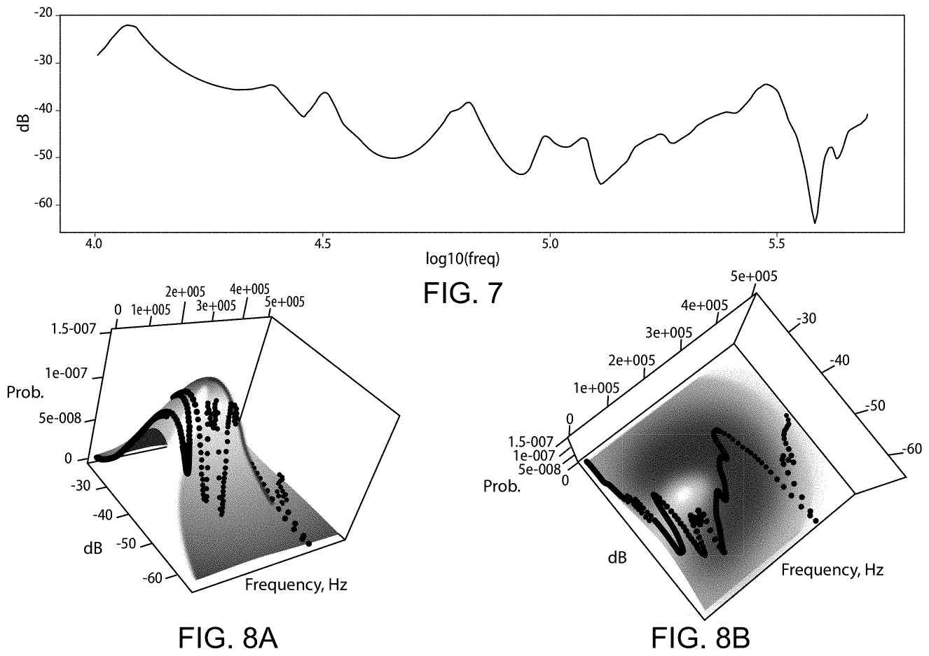

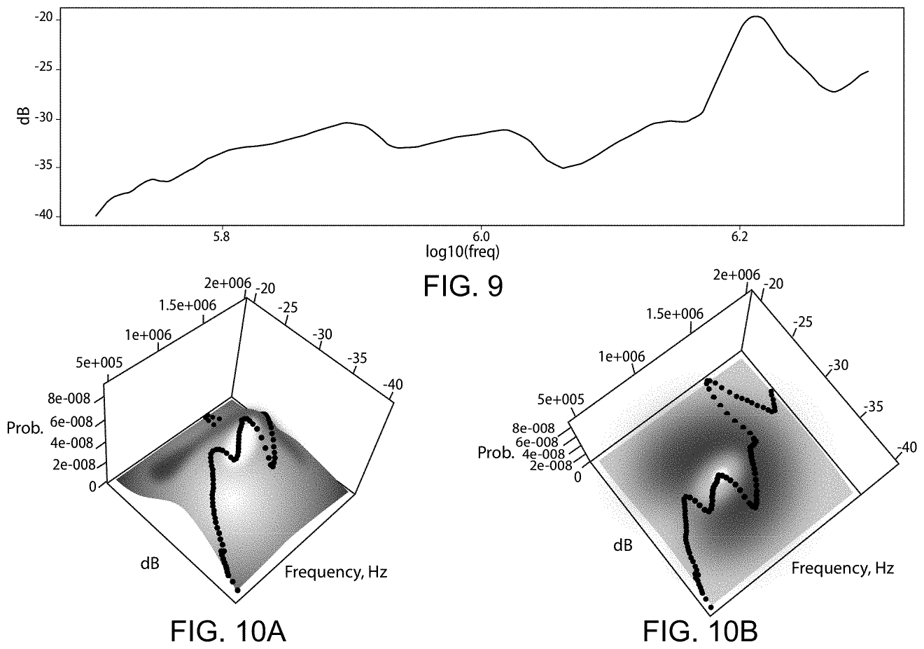

A segment of the chart of FIG. 2 is shown in FIG. 5 restricted to the frequencies of 1 kHz to 10 kHz. Corresponding three-dimensional charts are also shown in FIG. 6A-6B. Another segment of the chart of FIG. 2 is shown in FIG. 7 restricted to the frequencies of 10 kHz to about 500 kHz. Corresponding three-dimensional charts are also shown in FIGS. 8A-8B. Another segment of the chart of FIG. 2 is shown in FIG. 9 restricted to frequencies above 500 kHz. Corresponding three-dimensional charts are also shown in FIGS. 10A-10B. As illustrated in each of the three-dimensional charts, the pattern of the trace of the frequency and dB data is smooth and readily identifiable.

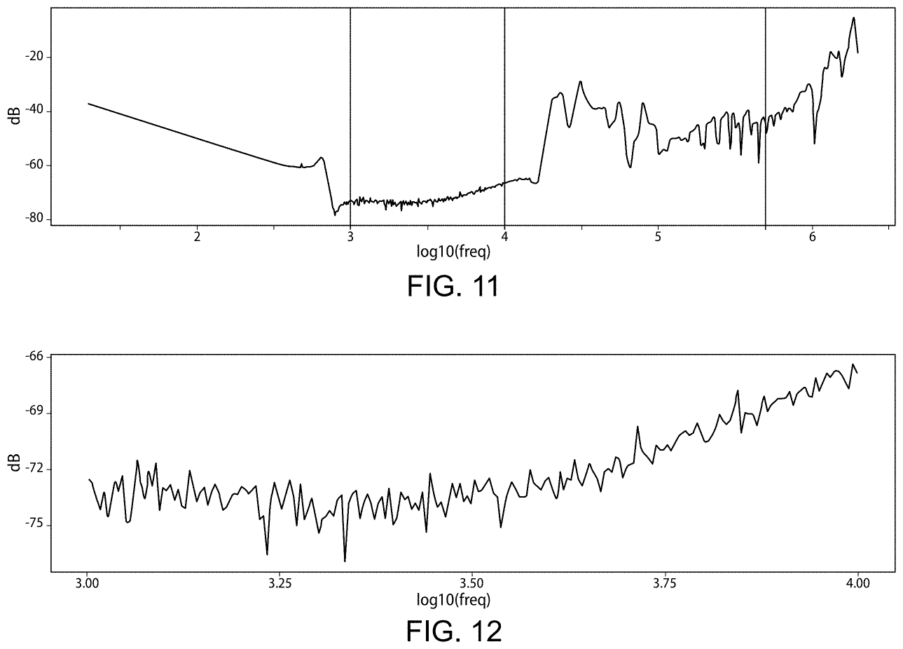

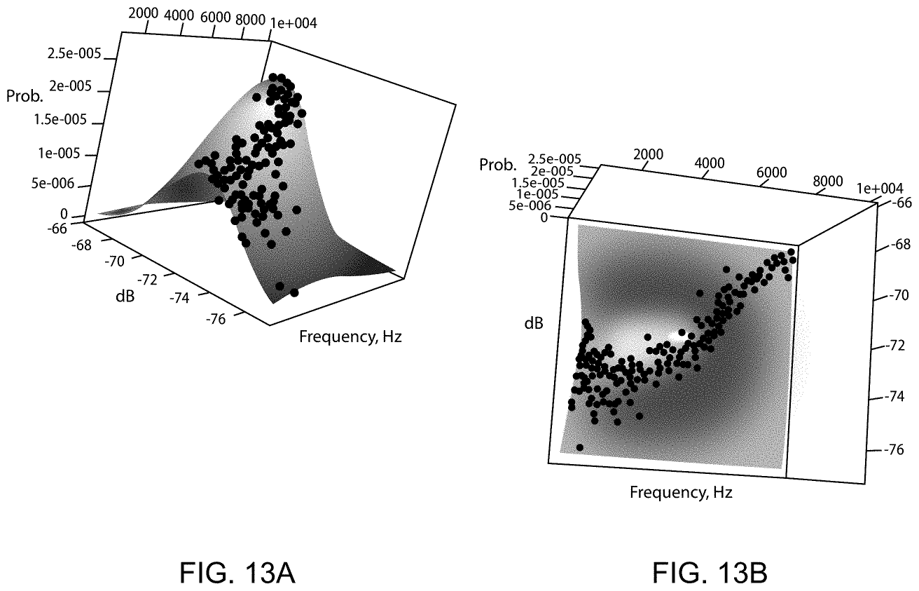

In FIG. 11, a frequency response analysis chart is shown with unusual noise in the range of 1-10 kHz. A segment of the 1-10 kHz data is shown in FIG. 12. In FIGS. 13A-13B, the data is shown in a three-dimensional chart as described above with a probabilistic surface. As shown, the pattern of the trace of the data is noticeably spread out and choppy.

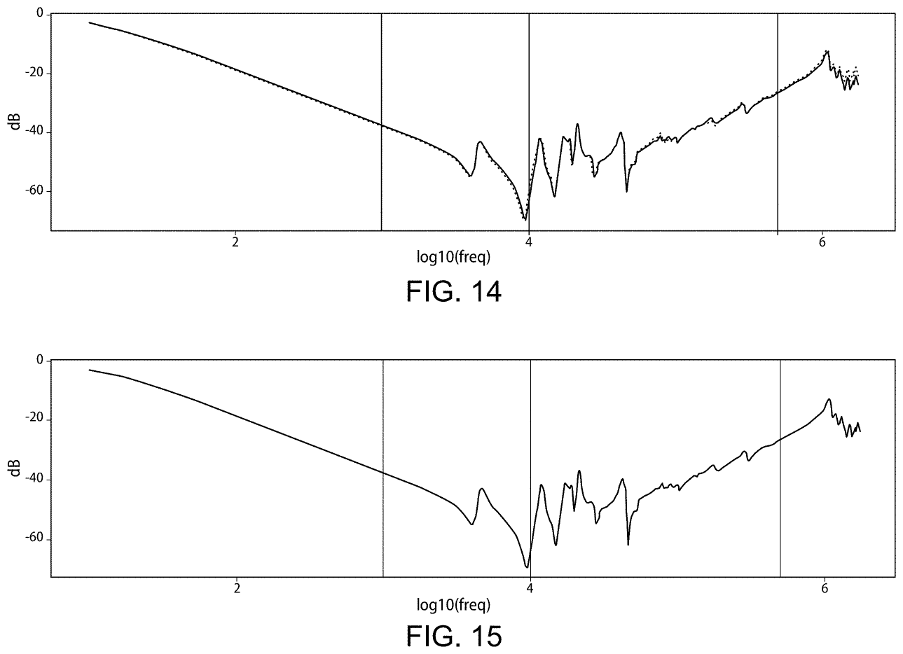

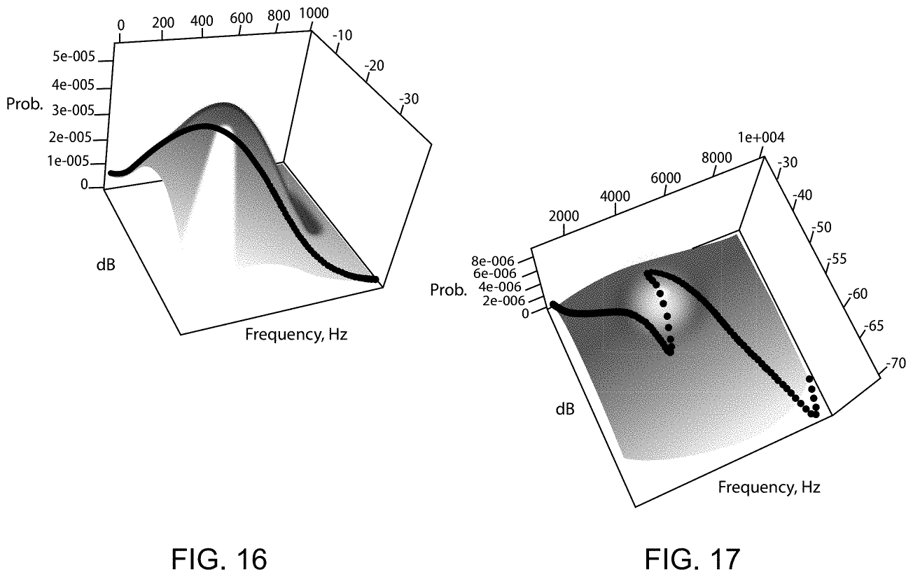

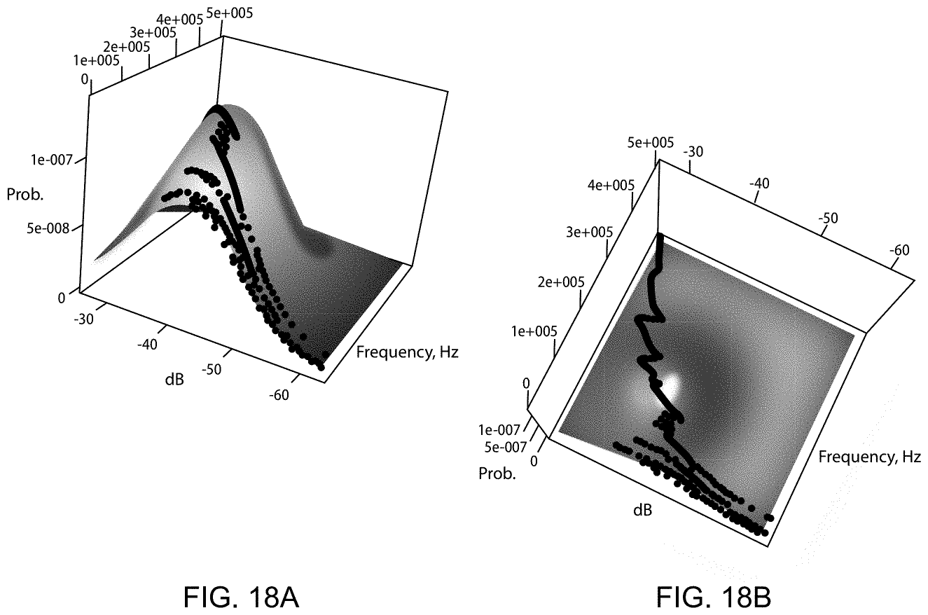

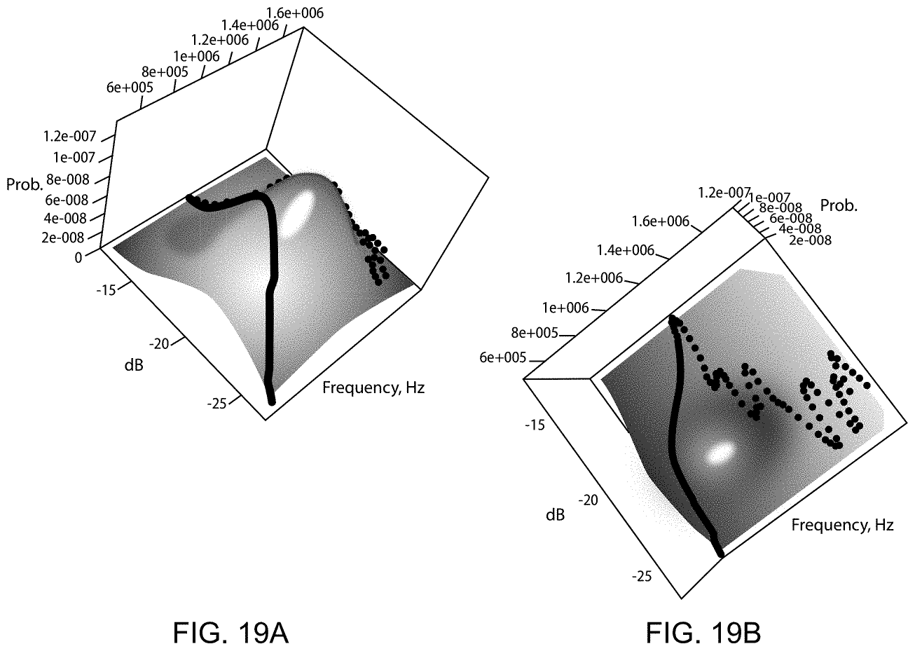

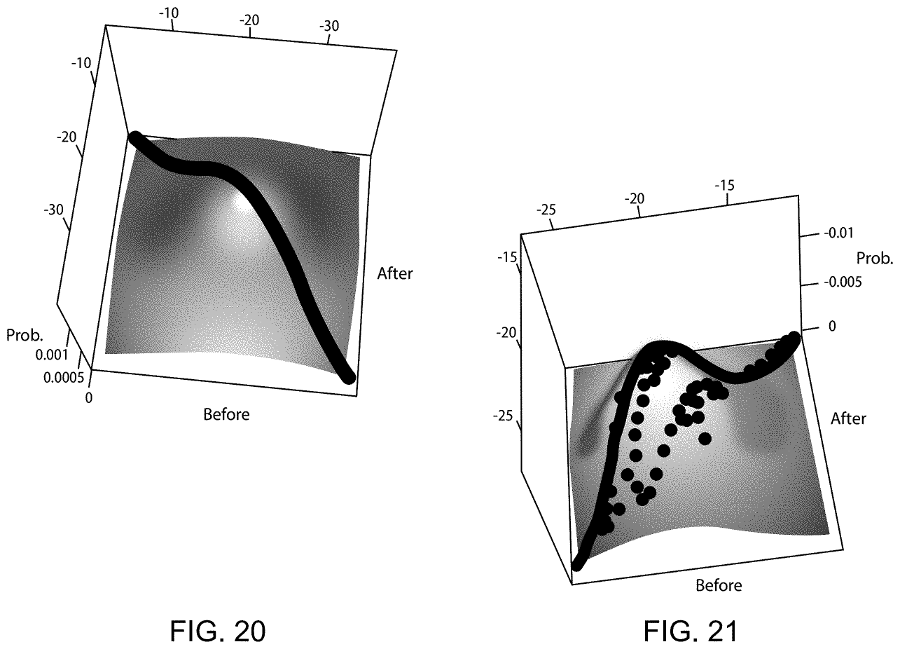

FIG. 14 shows a frequency response analysis chart with data from an initial test and data from a later test. FIG. 15 shows the chart with only the initial test data. FIGS. 16-19B show three-dimensional charts of the initial test data with probabilistic surfaces and traces thereon of the data. As illustrated, the initial data is distinguishable on the three-dimensional charts with smooth traces. FIGS. 20 and 21 show three-dimensional charts for the data of FIG. 14 with traces for the initial test data and the later test data. FIG. 20 is for the frequencies below 1 kHz and FIG. 21 is for the frequencies above 500 kHz. Unlike the previous three-dimensional charts, FIGS. 20 and 21 use dB for two axes and probability for the third axis. That is, one axis is defined by the dB data of the initial test and another axis is defined by the dB data of the later test. The probabilistic surface is generated in a similar way as described above, but the two statistical distributions that are used are based on the before and after dB data (i.e., amplitude) instead of on frequency and dB. As shown in FIG. 20, the pattern of the trace for the initial and later test data is smooth and uniform, indicating that there has been no change in the windings of the transformer between the tests. On the other hand, in FIG. 21 the pattern of the trace for the initial and later tests is seen as having discontinuous and choppy regions. Thus, it is apparent that there has been a change in the windings between the two tests.

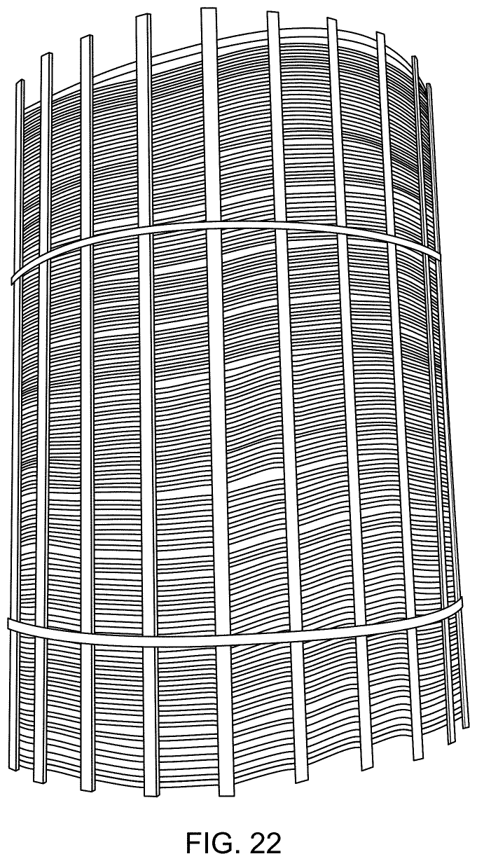

An example of an anomaly that may happen to a winding of a transformer between two tests is shown in FIG. 22. As shown, the winding has been deformed. Although this may be caused by a variety of events, one possible cause is an electrical short or fault that causes excessive heat in the winding. Typically, the winding will be enclosed within a transformer housing and may be immersed in a cooling fluid. Thus, it may not be easy, and it is typically very expensive, to visually inspect a transformer winding. However, by using a frequency response analysis with the method described above, anomalies may be identified more easily and cheaper and potential failures may be identified before an actual failure occurs.

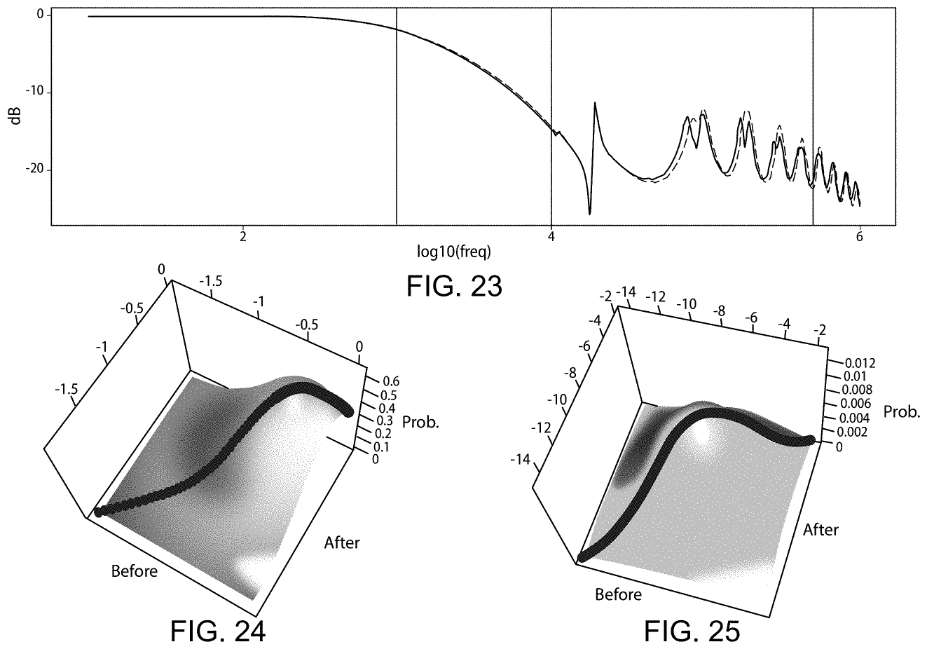

Another example of before and after frequency response analysis data is shown in FIG. 23. One circumstance where before and after test data may be used is when the transformer is manufactured and the manufacturer runs an initial test on the transformer at the factory. A subsequent test may then be run when the transformer is installed at the final site where it will be used to ensure that it has been installed correctly and that no damage has occurred between the factory and final installation, such as during transportation or installation. Tests may also be done at regular maintenance intervals to ensure that the transformer windings are still in good condition. It is understood that the test equipment connections to the transformer should be the same in both tests so that the only differences in the data between the tests will be attributed to some change in the windings between the tests.

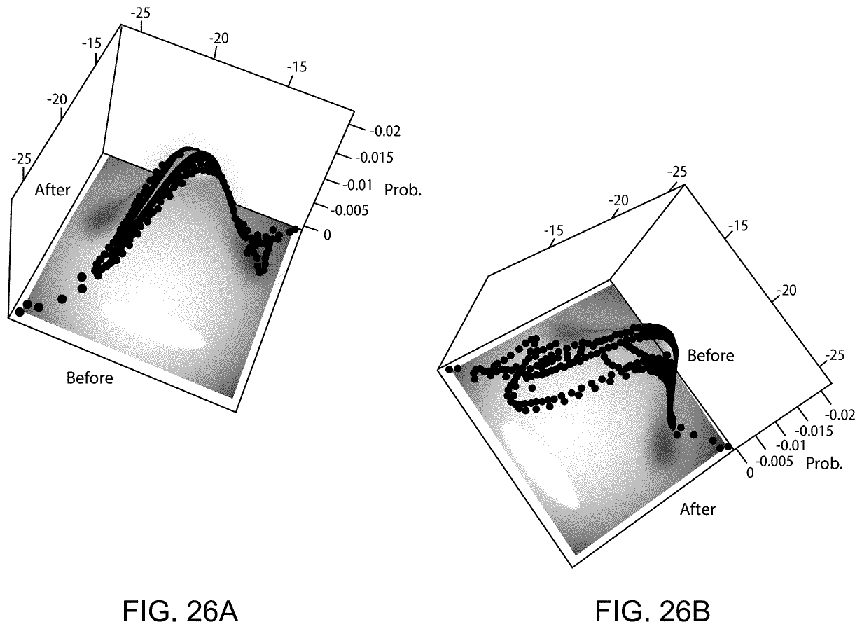

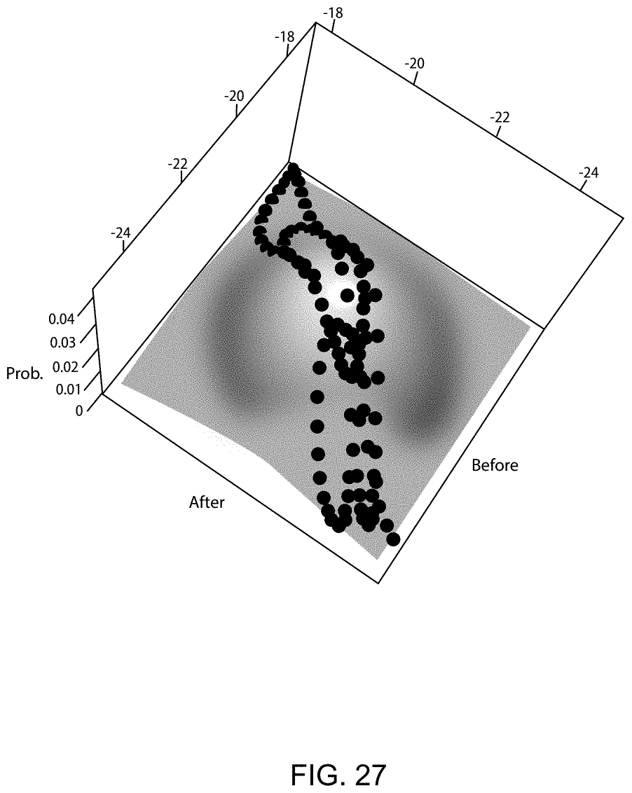

The three-dimensional charts of FIGS. 24-27 are based on the tests of FIG. 23. Like FIGS. 20-21, the axes are dB before, dB after and probability. FIG. 24 covers frequencies below 1 kHz and FIG. 25 covers frequencies between 1 kHz and 10 kHz. As shown, the before and after traces are smooth and continuous, indicating that no winding anomalies have occurred that affect these frequencies. However, FIGS. 26A-26B covering frequencies from 10 kHz to 500 kHz and FIG. 27 covering frequencies above 500 kHz show noticeable pattern spread in the traces, which indicates that an anomaly has occurred that affects these frequency ranges.

While the method described herein may be particularly useful in identifying anomalies with three-dimensional charts as illustrated, it is understood that other comparisons may also be done. For example, computer algorithms may use the combined first and second statistical distributions to analyze patterns of the amplitude and/or frequency data. As recognized, it is also possible to use the method herein to analyze data from a single frequency response test or to compare data from two different frequency response tests performed at different times.

While preferred embodiments of the inventions have been described, it should be understood that the inventions are not so limited, and modifications may be made without departing from the inventions herein. While each embodiment described herein may refer only to certain features and may not specifically refer to every feature described with respect to other embodiments, it should be recognized that the features described herein are interchangeable unless described otherwise, even where no reference is made to a specific feature. It should also be understood that the advantages described above are not necessarily the only advantages of the inventions, and it is not necessarily expected that all of the described advantages will be achieved with every embodiment of the inventions. The scope of the inventions is defined by the appended claims, and all devices and methods that come within the meaning of the claims, either literally or by equivalence, are intended to be embraced therein.

1. A method of identification of abnormal winding response when testing a transformer using frequency response analysis (FRA), comprising:
applying a first AC voltage to a first winding and varying a frequency of the first AC voltage in one or more frequency response tests;
measuring an amplitude and a frequency of a second AC voltage of a second winding in each of the one or more frequency response tests, the second AC voltage being produced in response to the first AC voltage;
generating a first statistical distribution based on the amplitude or frequency of the second AC voltage;
generating a second statistical distribution based on the amplitude or frequency of the second AC voltage;
wherein the first and second statistical distributions are based on different amplitude or frequency data for a common range of frequencies from a same frequency response test or different frequency response tests;
combining the first and second statistical distributions together with the first statistical distribution defining a first axis, the second statistical distribution defining a second axis, and probabilities of the first and second statistical distributions defining a third axis.

2. The method according to claim 1, wherein the first statistical distribution is based on the frequency of the second AC voltage and the second statistical distribution is based on the amplitude of the second AC voltage of the same frequency response test.

3. The method according to claim 1, wherein the first statistical distribution is based on the amplitude of the second AC voltage and the second statistical distribution is based on the amplitude of the second AC voltage of the different frequency response tests.

4. The method according to claim 1, wherein the amplitude of the second AC voltage is expressed as a ratio of the first and second AC voltages.

5. The method according to claim 2, wherein the amplitude of the second AC voltage is expressed as a decibel (dB) determined by 20*log(the second AC voltage/the first AC voltage).

6. The method according to claim 1, wherein the first statistical distribution is a Gaussian distribution defined by a mean and a standard deviation.

7. The method according to claim 1, wherein the second statistical distribution is a Gaussian distribution defined by a mean and a standard deviation.

8. The method according to claim 1, further comprising overlaying the different amplitude or frequency data for the common range of frequencies on the combined first and second statistical distributions, and identifying an anomaly of the transformer based on a pattern of the overlayed data.

9. The method according to claim 8, wherein the anomaly comprises a deformation in the first or second windings.

10. The method according to claim 1, further comprising generating a three-dimensional chart with the first axis, second axis and third axis, and plotting the different amplitude or frequency data for the common range of frequencies on the three-dimensional chart.

11. The method according to claim 10, further comprising plotting a probabilistic surface on the three-dimensional chart representing the first and second statistical distributions.

12. The method according to claim 1, wherein the first statistical distribution is based on the amplitude of the second AC voltage and the second statistical distribution is based on the amplitude of the second AC voltage of the different frequency response tests, further comprising overlaying the different amplitude or frequency data for the common range of frequencies on the combined first and second statistical distributions, and identifying an anomaly of the transformer based on a pattern of the overlayed data, wherein the anomaly comprises a deformation in the first or second windings which occurs between the different frequency response tests.

13. The method according to claim 12, further comprising generating a three-dimensional chart with the first axis, second axis and third axis, and plotting the different amplitude or frequency data for the common range of frequencies on the three-dimensional chart.

14. The method according to claim 13, further comprising plotting a probabilistic surface on the three-dimensional chart representing the first and second statistical distributions.

15. The method according to claim 14, wherein the amplitude of the second AC voltage is expressed as a ratio of the first and second AC voltages.

16. The method according to claim 15, wherein the first statistical distribution is a Gaussian distribution defined by a mean and a standard deviation, and the second statistical distribution is a Gaussian distribution defined by a mean and a standard deviation.

17. The method according to claim 1, wherein the first statistical distribution is based on the frequency of the second AC voltage and the second statistical distribution is based on the amplitude of the second AC voltage of the same frequency response test, further comprising generating a three-dimensional chart with the first axis, second axis and third axis, plotting the different amplitude or frequency data for the common range of frequencies on the three-dimensional chart, overlaying the different amplitude or frequency data for the common range of frequencies on the combined first and second statistical distributions, and identifying an anomaly of the transformer based on a pattern of the overlayed data.

18. The method according to claim 17, further comprising plotting a probabilistic surface on the three-dimensional chart representing the first and second statistical distributions.

19. The method according to claim 18, wherein the first statistical distribution is a Gaussian distribution defined by a mean and a standard deviation, and the second statistical distribution is a Gaussian distribution defined by a mean and a standard deviation.

20. The method according to claim 19, wherein the amplitude of the second AC voltage is expressed as a ratio of the first and second AC voltages.
